(19) United States
(12) Patent Application Publication
(10) Pub. No.: US 2011/0130994 A1
(43) Pub. Date: Jun. 2, 2011

(54) CIRCUIT AND METHOD FOR DETERMINING A VALUE, PARTICULARLY A DURATION, OF A TEST SIGNAL

(75) Inventor: MARTIN MELLERT, Steinach (DE)

(73) Assignee: VEGA Grieshaber KG, Wolfach (DE)

(21) Appl. No.: 12/869,105

(22) Filed: Aug. 26, 2010

Related U.S. Application Data
(60) Provisional application No. 61/266,795, filed on Dec. 4, 2009.

(30) Foreign Application Priority Data
Dec. 1, 2009 (EP) EP 09 014 867.7

(51) Int. Cl. G06F 19/00; G01R 29/00

(52) U.S. Cl. 702/79

(57) ABSTRACT

The invention is related to a method and a circuit for determining a value, particularly a duration, of a test signal, in which a timer is executed with a first clock-state change of a clock to apply a control signal to at least a first of at least two delay elements. The delay elements are executed to produce different time-delayed comparison signals. A comparator arrangement with at least one comparator with comparator inputs, to apply the differently delayed comparison signals and the instantaneous test signal, is designed to determine, from the respective applied comparison signal and the test signal, a comparison result, whereby the sequence of the comparison results forms a differential value for the test signal.

### CROSS REFERENCE TO RELATED APPLICATIONS

This application claims priority from European Patent Application Serial No. 09 014 867.7, filed Dec. 1, 2009 and U.S. Provisional Patent Application Ser. No. 61/266,795 filed Dec. 4, 2009; the entire contents of which is herein incorporated fully by reference.

### REPRESENTATIVE FIGURE

FIG. 1.

### BACKGROUND OF THE INVENTION

1. Field of the Invention

The present invention relates to a circuit and a method for determining a value. More specifically, the present invention relates to a circuit and a method for determining a duration of a test signal.

2. Description of the Related Art

In general, determining a test value with sensors is well-known by means of frequency measurement using a test-value trigger, which is defined by a frequency of a clock and a duration of a test signal, or a duration of the state of a test signal. Here, a timer determines the duration of the test signal using the duration of the clock periods counted. Thus, the accuracy required for the test-value trigger is limited by the duration of the clock period. With a test signal, particularly one repeated periodically with a test frequency, the test-value trigger is determined by means of the frequency of the timer or clock and by the test time or test duration. If the timer or clock runs at a frequency of 1 MHz, and a trigger of 14 bits is reached, then a test measurement lasts 1 μsec×2¹⁴=16.384 msec.

What is not appreciated by the related art is that if the trigger is increased, a longer test time is required, or a timer is needed, which operates at a higher clock rate. The use of a timer with a higher clock rate, however, is associated with additional power consumption.

Accordingly, there is a need for an improved circuit and a method which make a higher trigger possible by simple means, whereby, in particular, an increase in the current consumption will turn out to be as small as possible.

### ASPECTS AND SUMMARY OF THE INVENTION

An aspect of the present invention is to provide a circuit and a method which make a higher trigger possible by simple means, whereby, in particular, an increase in the current consumption will turn out to be as small as possible.

This problem is solved by means of a circuit for determining a value, particularly a duration of a test value, with the features described herein and by means of a method for determining a value, particularly a duration of a test signal, as further described herein. Independently advantageous is a system with a sensor and such a circuit and methodology. Advantageous embodiments are the subject of dependent claims.

Preferable, according to this invention, is a circuit for determining a value, particularly a duration, of a test signal, in which a timer is executed or controlled at a first clock-state change of a clock to apply a control signal to at least a first of at least two delay elements. The delay elements are executed or controlled temporally to produce differently delayed comparison signals. An arrangement of comparators in the circuit is hooked up to at least one comparator, in which a first comparator input is connected respectively to apply one of these differently delayed comparison signals and a second comparator input is connected respectively to apply the test signal, is designed or controlled to determine a comparison result from the respective applied comparison signal and the test signal, in which the sequence of comparison results forms a differential value of the test signal.

Such a circuit makes possible, in a simple way and manner, the determination of a differential value which in the end yields the duration of a state of the test signal in the time range within a clock period. Here, trigger accuracy results due to the number of delay elements used or the comparison results. The use of only two delay elements offers an increase in accuracy of about a factor of 2, because the end of a signal state of the test signal can be precisely detected at the half-cycle period. The use of three delay elements makes possible an accuracy of up to one third of a clock period, and so on. Consequently, a test frequency that is at least predictable, or the duration of the state of a test signal, can be simply determined from the state change of the clock that was counted last.

By specifying that components such as the timer or the delay elements are “executed or controlled”, it is understood that such components can be executed by means of pure hardware components, in which, however, an embodiment can likewise be embedded by means of appropriately controlled processors or a combination of so-called hardware and software, especially firmware. The component features consequently result from the respective technology used for building such a circuit. Provided that control by components is planned, a corresponding algorithm or an appropriate control program is also recorded in an advantageous manner in a memory of the circuit, in order to be able to control the component effectively.

An arrangement of comparators is preferred with one comparator for each delay element such that each of the comparators applies a comparison signal and the respective instantaneous test signal. Equivalent to this, however, an arrangement can be executed in which a single comparator receives the different time-delayed comparison signals applied, one after the other, and compares them with the instantaneous value of the test signal. In this case, storage of the comparison results is carried out effectively, one after the other, in different register locations of a register. However, storage of the different comparison results from such different comparators can also be advantageously provided in one register.

The term “differential value” is understood to be a value of a test-signal duration during which the test signal maintains its state within the clock period and within the scope of trigger accuracy.

The term “clock” is understood to be a cycle that is used according to a preferred application for numbers or for determining a duration of a state for the test signal. At the same time, however, an independent cycle must be involved. Also, an existing cycle can be employed as the clock for use in the circuit.

A circuit is preferred in which an input of a delay element from a second or a further such delay element is connected, for applying the control signal, to an output of the comparison signal as a control signal of one of the delay elements previously configured for this delay element. Thus, the comparison signal of the delay element provided serves as a control signal for the delay elements downstream.

The term “connected” implies that the circuit is designed such that values or states of an output of a component are applied directly through a line or indirectly through intermediary components, if need be, to an input of the other component concerned. In particular, the term is consequently understood to refer to a line which links the corresponding inputs and outputs together.

Alternatively to this, or also in combination with this, an output can be also hooked up in a circuit to emit the control signal from the timer, to one input of at least two of the delay elements, and the delay elements can be executed or controlled to make differently delayed comparison signals available by means of delay durations of different lengths. Alternatively, the control signal can consequently also be applied to delay elements connected in parallel, each of which assumes, in particular, a longer delay at a desired quotient value. With such an embodiment, by means of additional diode circuits, for example, current flow is effectively eliminated between the inputs of the different delay elements, so that no current can flow out of one capacitor of one of the delay elements into another one of the delay elements.

With such circuits, at least one part of the delay elements exhibits an operational amplifier (op-amp), which is executed or controlled to emit the delay signal to the output of the delay element with the same value or state as the value or state of the control signal applied to the delay element or of a comparison signal. Therefore, it is preferable that the delay elements all be identically constructed and that all of them respectively cause an identically long delay up until the emission of the comparison signal produced by them.

The timer can be advantageously executed or controlled, at an edge change of the clock, to make the control signal available with a first specified state and can exhibit an output for emitting the control signal, which is connected to at least the first of the delay elements. In particular, it is consequently handled at the first specified state at a permanently pre-set voltage not equal to zero, which makes possible a continuous and uniform charging of a capacitative component, in particular of a capacitor, in the next delay element.

Preferably, such a circuit, in which the timer is executed or controlled, before a next edge change of the clock, makes a control signal available with a second state, and exhibits the output for emitting the control signal, which is connected to at least the first of the delay elements. In particular, it is handled at the second state, in particular also permanently specified with a voltage equal to zero. Consequently, it is important here that the termination of the first state of the control signal occur for the leading edge change before the expiration of a clock period. In the case of an initially dropping edge, this is accordingly a point in time before the next dropping edge of the clock.

In such a circuit, the timer is preferably executed or controlled to make the control signal available with the second state for a reconnect timepoint which, on the one hand, is smaller than the cycle period for the clock and on the other hand is larger than a quotient with a pre-set denominator and a numerator value equal to the denominator minus 1, in which the denominator is equal to a number of the delay elements or a number of comparators or a number of comparison results. By means of such a circuit, or methodology corresponding to it, the accuracy of determining the differential value can be combined in a simple way and manner with a number of delay elements or delay signals.

Preferably, in such a circuit, the delay elements are executed with a resistor-capacitor element, to which is connected an output of the timer, which emits the control signal, or an output of a preceding delay element which emits its comparison signal. According to one embodiment with delay elements executed in series, the control signal of the timer is applied to the first of the delay elements, while each delay signal of the preceding delay element is applied to the next delay element as its control signal. Based on each value or strength of the control signal or delay signal applied to the next delay element, an additional amplification, if necessary, or an adjusted application of the resistance-to-capacitance ratio of the resistor-capacitor element is appropriate.

According to one embodiment with delay elements connected in parallel, the control signal of the timer is applied to each of the delay elements as an input signal.

Thus, the delay elements are preferably accomplished with a gate, which is executed to cause the emission of the comparison signal for a point in time at which a capacitative component of the resistor-capacitor element has reached a pre-defined voltage to be obtained. Such a gate can, in particular, be executed in an op-amp downstream of the resistor-capacitor element. Optionally, a so-called Schmitt trigger can also be constructed, which preferably as an op-amp emits a specified comparison signal, if a pre-set capacitance is reached and consequently the length of the delay up until the emission of the comparison signal is leveled.

In particular, in such a circuit, at least one reset circuit can be connected, at the terminal clock-state change of a clock period or at a clock-state change signal depending thereon, to discharge the resistor-capacitor element, particularly to ground the capacitors in it.

A register can exhibit register locations which are connected to receive the comparison results of the comparator.

A method is also preferred according to this invention for determining a value, particularly a duration, of a test signal, in which at a first clock-state change of a clock a control signal is made available. Based on the control signal, comparison signals time-delayed differently from one another are produced, each of the differently delayed comparison signals is compared to the instantaneously applied test signal, and as a result of the comparison, one of the number of comparison signals corresponding to the number of comparison results is determined, in which the sequence of comparison results forms a differential value for the test signal. In particular, the control signal is applied to at least a first of at least two delay elements.

According to the method, it is advantageous if at a terminal clock-state change after a clock period or at a clock-state change signal dependent on it, the comparison results are read out as the differential value to be determined, and a register storing the comparison results is erased and resistor-capacitor elements of the delay elements are discharged.

The differential value thus made available is preferably to be added back to an integral numerator value of the test signal, whereby the numerator value of a number counted by the clock so far corresponds to the clock for determining the differential value of clock periods counted. Thus, a numerator value is thus made available, which corresponds not only to a whole number of cycles counted, but in addition to a component value determined for the last integral numerator value of the next cycle. In particular, subtracting the value of 1 minus the differential value from the numerator value of the clock at the termination of the clock for differential-value determination is equivalent to adding the differential value to the numerator value of the clock of the edge initiating the process.

Also, independently advantageous according to this invention is a system with a sensor with a test-value detection component, which emits a test signal, in particular a test frequency, and with a circuit for determining a duration or a value of the test signal. Especially advantageous here is a system which exhibits a sensor and a corresponding circuit. With this, the circuit can already be integrated into the sensor itself into a control module of the sensor. But, a multicomponent system is also possible, in principle, in which a signal delivered by a sensor is received and evaluated in evaluation equipment separate therefrom. In such a case, the circuit would be disposed in the separate equipment.

Consequently, a circuit and a method are made available, which in a simple way and manner cause a trigger increase without a change in test time or test duration and at the same clock rate, in which it zooms between the timer states and durations of the clock cycle periods. For example, the state-change of an edge is selected here as a circuit criterion from a high to a low test frequency or test signal. However, it is not known at which precise point in time the test frequency or the state of the test signal actually changes within the clock period from the high to the low state. With the additional circuit-specific hardware achieved, in particular the resistor-capacitor elements and the comparators, a historical value can be established however in the form of the differential value. This is additionally read out, after the test-signal change from the high to the low state, to an integral value of the number of clocks counted. With the arrangement depicted, an increase in the trigger from 14 bits to 16 bits is consequently attained if four delay elements and comparators are provided. By using further gates, the range can be still further triggered for the same test time.

Preferably, the edges of the timer are sent to a series of resistor-capacitor elements. Thus, delayed signals result. These signals are sent to a comparator, which passes its signal on to a register. Depending on the point in time at which the test signal has its edge change, a finer trigger is written into the register.

Such a circuit and such a method make it possible, in a simple way and manner, to detect a state change in the test signal (ms) as a test-signal circuit criterion, particularly from the high to the low state, and to detect a state change of the clock (clk) as a clock-circuit criterion, particularly from the high to the low state. But, with an appropriate switch in the circuit diagram or procedure, a state change from the low to the high state can also be used as the circuit criterion.

The above, and other aspects, features and advantages of the present invention will become apparent from the following description read in conjunction with the accompanying drawings, in which like reference numerals designate the same elements.

### BRIEF DESCRIPTION OF THE DRAWINGS

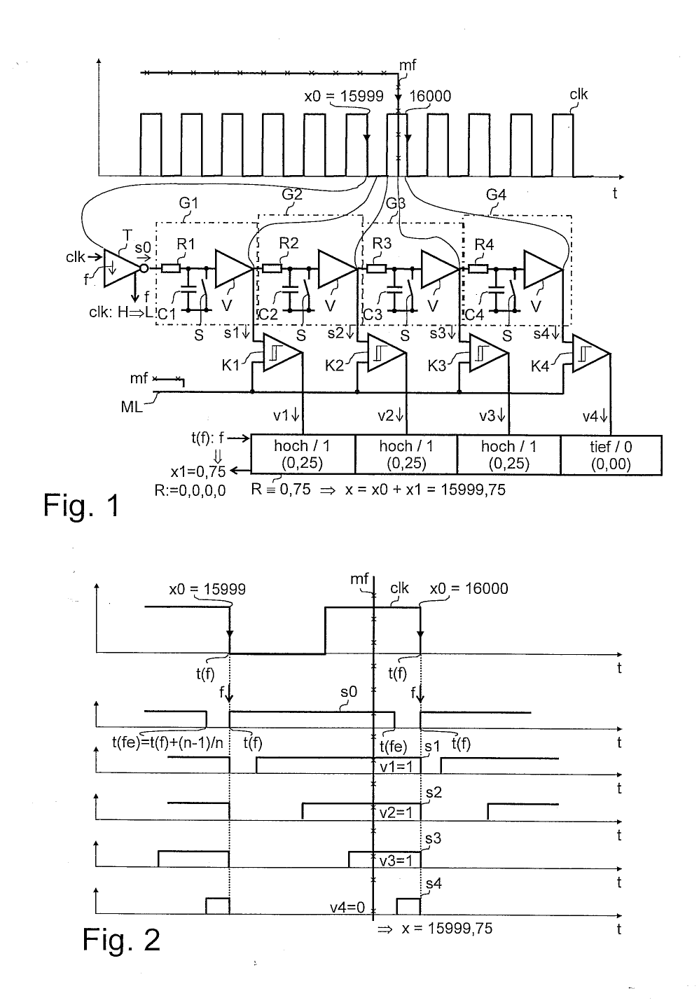

FIG. 1 is a schematic diagram of a signal path, as well as preferred components for evaluating the signal path.

FIG. 2 is a plot of signal paths plotted over time for different signals and states of the circuit diagram according to FIG. 1.

### DETAILED DESCRIPTION OF THE PREFERRED EMBODIMENTS

Reference will now be made in detail to several embodiments of the invention that are illustrated in the accompanying drawings. Wherever possible, same or similar reference numerals are used in the drawings and the description to refer to the same or like parts or steps. The drawings are in simplified form and are not to precise scale. For purposes of convenience and clarity only, directional terms, such as top, bottom, up, down, over, above, and below may be used with respect to the drawings. These and similar directional terms should not be construed to limit the scope of the invention in any manner. The words “connect,” “couple,” and similar terms with their inflectional morphemes do not necessarily denote direct and immediate connections, but also include connections through mediate elements or devices.

Turning to FIG. 1, there is shown, in the upper section, a signal path by way of example for a test signal mf applied over the propagation time t. In addition to this, a clock clk is plotted over the time t, which is available to be read off on a preferred circuit diagram or is produced by means of the circuit. Using the clock clk, the duration of the test signal mf, or a test frequency, is determined.

For the case depicted by way of example, it is assumed that, with the dropping edge of the test signal mf from a first state into a second state of the test signal mf, integral numerator values x0 of the test signal mf or of the test frequency are leveled for a beginning state of this test signal of 15,999. The end of the test signal mf or its edge changed from the high state to the low state, however, lies between this and a next integral numerator value x0, so that accuracy for the determination can thus be defined only within the scope of accuracy for a cycle period of the clock clk. In the lower part of FIG. 1, by way of example, a circuit diagram is sketched for determining a differential value x1, which makes a more precise determination possible with respect to the timepoint for the drop in the edge of the test signal mf within the cycle period of the clock clk, which follows the last integral numerator value x0.

The circuit diagram exhibits a timer T which is executed or controlled to always emit a clock-state change signal f if a cycle period of the clock clk is detected. In the preceding example of an edge for triggering the clock-state change signal f, the dropping edge of the clock clk from the “high” state H to the “low” state L is considered by way of example.

According to a first preferred embodiment depicted, the control signal s0 is applied to a first delay element G1 in a group of delay elements G1, G2, G3, G4 connected in series. The delay element G1 causes a delayed output of a first comparison signal s1 at the point in time that the control signal is applied.

The first comparison signal (s1) is applied as a control signal to both the second delay element G2 and an input of a first comparison element or comparator (K1). In the same way, a second time-delayed comparison signal (s2) is emitted by the second time-delayed delay element G2 to apply the control or comparison signal (s1) to its input through its output. The second comparison signal s2 is accordingly applied to an input of a further comparator K2 and additionally to a input of a third delay element G3. The third of the delay elements G3 produces in the same way a time-delayed third comparison signal s3 which is once again applied to a third comparator K3 and to the fourth delay element G4. A fourth comparison signal s4 produced is only applied by the fourth delay element G4 to a still further comparator K4.

The comparison signals s1-s4 are consequently applied to the comparators K1-K4 whose first input is time-staggered. To a second input is applied the instantaneous test signal mf over a test-signal line ML for the respective comparators K1-K4. The comparators K1-K4 are preferably constructed as Schmitt triggers and emit a respective comparison result v1-v4.

In a preferred embodiment, then, a high state or a value of 1 is always given as a comparison result v1-v4, if both the applied comparison signal s1-s4 and the instantaneous test signal mf are found in the “high” state. Otherwise, a state value of “low” or a value of 0 is given as the comparison result v4. The comparison values v1-v3 are thus found in a high state or at the value of 1 as long as the test signal mf is found in the high state. After the change of the test signal mf into the low state, the comparison signal v4 is set in the low state or at a value of 0.

The comparison results of the comparators K1-K4 are preferably stored in register locations in a register R. For the example case, finally, the register locations for the end of the cycle period for the clock clk exhibit the values of R=1,1,1,0. Because the cycle period for the clock clk is divided into four in such an arrangement with four delay elements G1-G4, for example, the value of each one of the registers corresponds to a quarter of the duration of one cycle period.

For the example case, this means that the duration of a test signal mf with a value of about 3 times 0.25, that is, about 0.75, is longer than a point in time t(f) of the clock-state change triggering the trial for which the clock-state change signal is emitted. Consequently, a sum results as a value x added in to the test signal mf or its duration, made up of the integral numerator value x0 and such a differential value x1 which can be read out of the register R, such that x=x0+x1=15999.75.

In digital representation, this corresponds to an increase in a trigger from 14 bits to 16 bits when using four delay elements. For a further increase in the trigger, more such delay elements can be connected one after the other.

With the next dropping edge of the clock clk or the production of the next clock-state change signal f, the register R is read out and erased, so that the initial value of 0 stands in all the register locations. In addition to this, with the application of the clock-state change signal f using at least one reset switch S, preferably using one reset state switch S per delay element G1-G4, a capacitative component is discharged, and, in particular is grounded.

The capacitative components are, by way of example, constructed as capacitors C1-C4 and a component respectively of resistor-capacitor elements R1, C1; R2, C2; R3, C3; R4, C4 each with at least one ohmic component, for instance the resistors R1-R4, and a capacitative component in the form of capacitors C1-C4. The control signal is applied respectively to the resistor-capacitor elements R1, C1; R2, C2; R3, C3; R4, C4 of the delay elements G1-G4, that is, in the first case, the control signal s0 of the timer T or in the case of further delay elements G2-G4 the comparison signal s1-s3 of the previously connected delay elements G1-G3. By way of example, the respective control or comparison signal s0-s3 is thus each applied to a corresponding input of the resistor component, while an output of the resistor component is applied to both the capacitative component and to an input of an amplifier V, in particular to an op-amp. A second input of the capacitative component is grounded. The attached reset switch S goes to ground connection to discharge at the connection point between the capacitative and the ohmic components.

The amplifier serves to amplify the voltage built up in the capacitative component and to emit the corresponding comparison signal s1-s4.

The amplifier V can thus also exhibit a gate, which then emits the corresponding comparison signal first when the capacitative component applies a sufficiently increased voltage is applied to the input of the amplifier. Preferably therefore, identically constructed delay elements can be connected in series. In addition, identically constructed comparators K1-K4 can also be used.

Alternative embodiments can also be realized, in principle. In the case of a comparison signal s1-s4, which is emitted continuously depending on a instantaneous voltage of the capacitative quantity, the comparators K1-K4 would accordingly be connected, so that upon exceeding a pre-set voltage, a comparison would be made with the instantaneously applied test signal mf. It is also to be considered then, by way of example, that the comparison signals of the following delay elements would be emitted with a respectively lower voltage.

Turning next to FIG. 2, there are shown different states plotted over time t using the signals described in FIG. 1.

On the top line, a clock clk period is depicted beginning with a first dropping edge for a first point in time t(f) of the clock-state change and ending with a point in time t(f) of a next clock-state change. For each of these points in time, the clock-state change signal f is emitted. Consequently, a notch is depicted for a clock clk beginning with the integral numerator value x0 of 15999 and ending with the integral numerator value x0 of 16000 for the clock elk.

On the second line, the control signal s0 is depicted which is emitted by the timer T. The control signal s0 changes respectively with the application or production or timepoint of the clock-state change signal f from the low to the high state. The control signal s0 is preferably made available with a first specified state.

A duration of the first specified state of the control signal s0 depends on the number of delay elements G1-G4. In each case, it is shorter than a full cycle period for the clock clk. In addition to this, the control signal s0 is larger or longer than a quotient with a pre-set denominator n and a numerator value, in which the numerator value is equal to the denominator n minus 1 and in which the denominator n is equal to a number of delay elements G1-G4 or a number of comparators K1-K4 or a number of comparison results v1-v4. A reconnect time point t(fe) of the preferred change for the control signal s0 into the other, second specified state, in particular a change from the “high” state to the “low” state or from state 1 to state 0, can consequently be determined using t(fe)=t(f)+(n−1)/n.

In the third line, a time plot is depicted for the first comparison signal s1, which preferably changes once again between a low and a high state or the state values of 0 and 1. A rising edge of the first comparison signal s1 depends on the charge path of the resistor-capacitor elements R1, C1 in the first delay element G1. This is so dimensioned or executed that the rising edge of the first comparison signal s1 lies as close as possible, both at the timepoint and ahead of the timepoint, to a quarter period of the clock elk. A reset into the low state of the first comparison signal s1 occurs with the next clock-state change signal f or at the next time point t(f) of the clock-state change.

In the next line, the states are depicted for the three next comparison signals s2-s4, which are produced in a way and manner comparable to the first comparison signal s1. However, the rising edge is time-delayed respectively at a duration corresponding to a quarter of the cycle period for the clock elk.

Besides this, the time point of the edge or of the state change of the test signal mf is depicted as a vertical line. This point in time lies, by way of example, in a temporal region in the last quarter of the cycle period for the clock elk. Thus, signal states each occur in the high state for the first three comparison signals s1-s3 and the test signal mf, which corresponds to a value of 1 for each of its comparison results v1-v3, which is written into the first three register locations in the register R. During the period of the “high” or “1” state of the fourth comparison signal s4, the state of the test signal mf however is in the “low” state, so that the comparison result v4 in the fourth comparator K4 brings a value of 0, which is written into the fourth register location of the register R.

Consequently, from the fundamental notion of the circuit diagram and methodology, delay signals are produced here which are compared as to their state with a test-signal value, in order to more finely subdivide the duration of a cycle period for the clock clk. To attain this goal, basic modifications of the circuit diagram depicted and the methodology can also be carried out, by way of example.

For instance, according to an alternative embodiment not depicted, the four delay elements G1-G4 can be connected not in series but in parallel. In the case of such a parallel hook-up, the control signal s0 is applied to the input of each such delay element connected in parallel. In a more suitable manner, back flow of a current from the capacitative component of such a delay element into the other delay elements is prevented by means of an additional diode.

According to a further alternative embodiment, a single comparator can be used instead of a number of comparators K1-K4. For the conversion, then, the outputs of the different delay elements G1-G4 temporally displaced from one another are applied to the one comparator.

Naturally, another time plot can be selected in connection with the erasure and discharge. Especially advantageously, a read out and erasure of the register R can also be performed as well as a discharge of the resistor-capacitor element of the respective delay element just before the point in time for the state change of the clock clk.

In the claims, means or step-plus-function clauses are intended to cover the structures described or suggested herein as performing the recited function and not only structural equivalents but also equivalent structures. Thus, for example, although a nail, a screw, and a bolt may not be structural equivalents in that a nail relies on friction between a wooden part and a cylindrical surface, a screw's helical surface positively engages the wooden part, and a bolt's head and nut compress opposite sides of a wooden part, in the environment of fastening wooden parts, a nail, a screw, and a bolt may be readily understood by those skilled in the art as equivalent structures.

Having described at least one of the preferred embodiments of the present invention with reference to the accompanying drawings, it is to be understood that the invention is not limited to those precise embodiments, and that various changes, modifications, and adaptations may be effected therein by one skilled in the art without departing from the scope or spirit of the invention as defined in the appended claims.

What is claimed is:

1. A circuit for determining a value, particularly a duration, of a test signal, in which a timer is executed or controlled, at a first clock-state change of a clock, to apply a control signal to at least a first of at least two delay elements of a plurality of delay elements, and said plurality of delay elements are executed or controlled to produce time-delayed comparison signals different from one another, said circuit further comprising:
(a) a comparator arrangement with at least one comparator, in which:
(i) a first respective comparator input is connected to apply one of said differently delayed comparison signals; and
(ii) a second respective comparator input, to apply the test signal, is designed or controlled by the respective applied comparison signal and the test signal respectively to determine a comparison result wherein a sequence of comparison results forms a differential value for the test signal.

2. A circuit according to claim 1, in which, from a second or a further delay element of said plurality of delay elements, an input for applying said control signal is connected to an output for emitting said comparison signal as a control signal of a set of delay elements configured previously to one of said at least two delay elements.

3. A circuit according to claim 1, in which an output for emitting said control signal of said timer is also connected to an input of said at least two of said plurality of delay elements, and said plurality of delay elements executed or controlled and make differently delayed said comparison signal available by means of delay durations of different lengths.

4. A circuit according to claim 3, in which at least one portion of said plurality of delay elements exhibits an operational amplifier, which is executed or controlled to emit said delay signal to one of said output of said plurality of delay elements with an identical value or state as the value or state of said control signal applied to one of said plurality of delay elements or said comparison signal.

5. A circuit according to claim 4, in which said timer is executed or controlled, at an edge change of said clock, to make said control signal available at a first specified state and exhibits an output for emitting said control signal, which is connected to at least the first of said plurality of delay elements.

6. A circuit according to claim 5, in which said timer is executed or controlled, before a next edge change of said clock, to make said control signal available at a second state and exhibit an output for emitting said control signal, which is connected to at least the first of said plurality of delay elements.

7. A circuit according to claim 6, in which said timer is executed or controlled, to make said control signal available with the second state for a reconnect timepoint, which on the one hand is shorter than a cycle period of said clock and on the other hand is larger than a quotient with a pre-set denominator and a numerator value equal to said denominator minus 1 (n−1), whereby said denominator is equal to a number selected from the group further comprising:
(a) said plurality of delay elements;
(b) a plurality of comparators; and
(c) said plurality of comparison results.

8. A circuit according to claim 7, in which each one of said plurality of delay elements are executed with a resistor-capacitor element of a plurality of resistor-capacitor elements, to which is connected an output of said timer, which emits said control signal, or an output of said preceding delay element, which emits said comparison signal.

9. A circuit according to claim 8, in which each of said plurality of delay elements is accomplished using a gate, said gate being executed to cause an emission of said comparison signal, for which a capacitative component of at least one of said plurality of resistor-capacitor elements has reached a pre-defined voltage to be obtained.

10. A circuit according to claim 9, in which at least one reset switch can be connected, at the terminal clock-state change of said clock period, or at a clock-state change signal dependent thereon, to discharge said at least one resistor-capacitor element, particularly a set of capacitors in said at least one resistor-capacitor element, especially to ground said at least one resistor-capacitor element.

11. A circuit according to claim 7, which exhibits a register with a plurality of register locations, which are connected to a pick-up the comparison results of said plurality of comparators.

12. A method for determining a value, particularly a duration, of a test signal, said method comprising the steps of:
(a) making a control signal available at a first clock-state change of a clock;
(b) producing a set of different time delayed comparison signals on the basis of said control signal;
(c) comparing each of said set of differently delayed comparison signals to an instantaneously applied test signal; and
(d) determining, as a result of said comparison, one of a plurality of comparison signals corresponding to a number of comparison results, in which the sequence of said comparison results forms a differential value for said test signal.

13. A method according to claim 12, in which at a terminal clock-state change after said clock period, or a clock-state change signal depending thereon, said comparison results are read out as the differential value to be determined, and a register storing said comparison results is erased and each of a plurality of resistor-capacitor elements corresponding to a plurality of delay elements is discharged.

14. A method according to claim 13, in which said differential value thus made available, is added back into an integral numerator value of said test signal, whereby said numerator value of a number counted by said clock corresponds to a second clock for determining a differential value of clock periods counted.

15. A method according to claim 13, said method further comprising the step of emitting said test signal, in particular a test frequency, from a system comprising:
(a) a sensor with a test-value detection component; and
(b) a circuit for determining a value, particularly a duration, of a test signal, in which a timer is executed or controlled, at a first clock-state change of a clock, to apply a control signal to at least a first of at least two delay elements of a plurality of delay elements, and said plurality of delay elements are executed or controlled to produce time-delayed comparison signals different from one another, said circuit further comprising:
(i) a comparator arrangement with at least one comparator, in which:
(1) a first respective comparator input is connected to apply one of said differently delayed comparison signals; and
(2) a second respective comparator input, to apply the test signal, is designed or controlled by the respective applied comparison signal and the test signal respectively to determine a comparison result wherein a sequence of comparison results forms a differential value for the test signal.

16. A method for determining a value for a duration of a test signal, said method comprising the steps of:
(a) controlling a timer, at a first clock-state change of a clock, to apply a control signal to at least a first of at least two delay elements of a plurality of delay elements, and said plurality of delay elements are executed or controlled to produce time-delayed comparison signals different from one another;
(b) employing a comparator arrangement, said comparator arrangement comprising at least one comparator;
(c) connecting a first respective comparator input to apply one of said differently delayed comparison signals; and
(d) controlling a second respective comparator input, to apply the test signal, by the respective applied comparison signal and the test signal respectively, to determine a comparison result wherein a sequence of comparison results forms a differential value for said test signal.

17. A method according to claim 16, said method further comprising the step of connecting from a second, or a further delay element of said plurality of delay elements, an input for applying said control signal to an output for emitting said comparison signal as a control signal of a set of delay elements configured previously to one of said at least two delay elements.

18. A method according to claim 16, said method further comprising the step of receiving, at said at least one comparator, each one of said time-delayed comparison signals in sequence at a different register location of a register.

19. A method according to claim 16, said method further comprising the steps of:
(a) connecting an output to said circuit for emitting a control signal;
(b) emitting said control signal from said timer to an input of said at least two of said delay elements; and
(c) executing said at least two of said delay elements so as to make available a set of two or more differently delayed comparison signals.

20. A method according to claim 16, wherein said differential value thus made available, is added back into an integral numerator value of said test signal, whereby said numerator value of a number counted by said clock corresponds to a second clock for determining a differential value of clock periods counted.
